(19) United States
(12) Patent Application Publication
(10) Pub. No.: US 2012/0009328 A1
(43) Pub. Date: Jan. 12, 2012

(54) THIN FILM DEPOSITION APPARATUS AND METHOD OF MANUFACTURING ORGANIC LIGHT-EMITTING DISPLAY DEVICE BY USING THE SAME

(76) Inventors: Jae-Kwang Ryu, Yongin-city (KR); Chang-Mog Jo, Yongin-city (KR); Hee-Cheol Kang, Yongin-city (KR)

(21) Appl. No.: 13/178,472

(22) Filed: Jul. 7, 2011

(30) Foreign Application Priority Data
Jul. 12, 2010 (KR) 10-2010-0066993

(51) Int. Cl. C23C 16/52; B05D 5/06; B05C 11/00

(52) U.S. Cl. 427/8; 118/712; 118/708; 427/66

(57) ABSTRACT

A thin film deposition apparatus that may be precisely aligned with a substrate during a deposition process, and a method of manufacturing an organic light-emitting display device using the thin film deposition apparatus.

### CLAIM OF PRIORITY

This application makes reference to, incorporates the same herein, and claims priority to and all benefits accruing under 35 U.S.C. §119 from an application earlier filed in the Korean Intellectual Property Office on 12 Jul. 2010 and there duly assigned Serial No. 10-2010-0066993.

### BACKGROUND

1. Field

One or more aspects of embodiments according to the present invention relate to a thin film deposition apparatus and a method of manufacturing an organic light-emitting display device by using the same.

2. Description of the Related Art

Organic light-emitting display devices have a larger viewing angle, better contrast characteristics, and a faster response rate in comparison with other display devices; therefore, the organic light-emitting display devices have drawn attention as a next-generation display device.

### SUMMARY

In order to solve the problems of the contemporary deposition method using a fine metal mask (FMM), one or more aspects of embodiments according to the present invention provide a thin film deposition apparatus that may be applied to simplify the production of large-sized display devices on a mass scale and that may be precisely aligned with a substrate during a deposition process, and a method of manufacturing an organic light-emitting display device by using the thin film deposition apparatus.

An aspect of embodiments according to the present invention provides a thin film deposition apparatus for forming a thin film on a substrate. The apparatus includes a deposition source for discharging a deposition material; a deposition source nozzle unit disposed at a side of the deposition source and including a plurality of deposition source nozzles arranged in a first direction; and a patterning slit sheet disposed opposite to the deposition source nozzle unit and having a plurality of patterning slits arranged in a second direction perpendicular to the first direction. Deposition is performed while the substrate is moved relative to the thin film deposition apparatus in the first direction. The patterning slit sheet has a first alignment mark and a second alignment mark that are spaced apart from each other. The substrate has a first alignment pattern and a second alignment pattern that are spaced apart from each other. The thin film deposition apparatus further includes a first camera assembly for photographing the first alignment mark and the first alignment pattern, and a second camera assembly for photographing the second alignment mark and the second alignment pattern.

The deposition source, the deposition source nozzle unit, and the patterning slit sheet may be integrally formed as a single body.

The deposition source and the deposition source nozzle unit, and the patterning slit sheet may be integrally connected as a single body by connection units which may guide the movement of the deposition material.

The connection units may be formed to seal a space between the deposition source, the deposition source nozzle unit, and the patterning slit sheet.

The plurality of deposition source nozzles may be tilted at an angle with respect to a vertical line of a surface from which the deposition source nozzles extrude. The plurality of deposition source nozzles may be tilted at a non-zero angle with respect to a vertical line of a surface from which the deposition source nozzles extrude.

The plurality of deposition source nozzles may include deposition source nozzles arranged in two rows in the first direction, and the deposition source nozzles in the two rows may be tilted towards each other.

The plurality of deposition source nozzles may include deposition source nozzles arranged in two rows in the first direction. The deposition source nozzles of one of the two rows located at a first side of the patterning slit sheet may be arranged to face towards a second side of the patterning slit sheet. The deposition source nozzles of the other of the two rows located at the second side of the patterning slit sheet may be arranged to face towards a first side of the patterning slit sheet.

The first alignment pattern may include a plurality of first marks arranged in the first direction. The second alignment pattern may include a plurality of second marks arranged in the first direction. The first alignment pattern and the second alignment pattern may be spaced apart from each other in the second direction.

At least one of the first mark or the second mark may have a polygonal shape.

At least one of the first mark or the second mark may have a triangular shape.

The first alignment pattern and the second alignment pattern may be formed in the form of a saw tooth.

A direction in which the first camera assembly and the second camera assembly are arranged may be perpendicular to the first direction.

The first camera assembly and the second camera assembly may be disposed over the substrate to correspond to the first alignment mark and the second alignment mark, respectively.

The thin film deposition apparatus may further include a controller for determining a degree to which the substrate and the patterning slit sheet are aligned with each other, based on information captured by the first camera assembly and the second camera assembly.

The controller may determine the degree to which the substrate and the patterning slit sheet are aligned with each other in the second direction perpendicular to the first direction by comparing a first distance between images of the first alignment pattern and the first alignment mark photographed by the first camera assembly with a second distance between images of the second alignment pattern and the second alignment mark photographed by the second camera assembly.

The controller may determine whether the patterning slit sheet is tilted within a plane formed by the first and second directions and is misaligned to the substrate by comparing an image of the first alignment mark photographed by the first camera assembly with an image of the second alignment mark photographed by the second camera assembly.

The controller may determine that the patterning slit sheet is tilted within the plane formed by the first and second directions towards the second alignment mark when a width of the image of the first alignment mark is greater than a width of the image of the second alignment mark, and may determine that the patterning slit sheet is tilted within the plane formed by the first and second directions towards the first alignment mark when the width of the image of the first alignment mark is less than the width of the image of the second alignment mark.

The controller may determine whether the substrate is tilted within the plane formed by the first and second directions and is misaligned to the patterning slit sheet by comparing an image of the first alignment pattern photographed by the first camera assembly with an image of the second alignment pattern photographed by the second camera assembly.

The controller may determine that the substrate is tilted within the plane formed by the first and second directions towards the second alignment pattern when a width of the image of the first alignment pattern is greater than a width of the image of the second alignment pattern, and may determine that the substrate is tilted within the plane formed by the first and second directions towards the first alignment pattern when the width of the image of the first alignment pattern is less than the width of the image of the second alignment pattern.

The substrate and the patterning slit sheet may be aligned with each other by moving the substrate or the patterning slit sheet, based on the degree of alignment, determined by the controller.

Another aspect of embodiments according to the present invention provides a thin film deposition apparatus for forming a thin film on a substrate. The apparatus includes a deposition source for discharging a deposition material; a deposition source nozzle unit disposed at a side of the deposition source and including a plurality of deposition source nozzles arranged in a first direction; a patterning slit sheet disposed opposite to the deposition source nozzle unit and having a plurality of patterning slits arranged in the first direction; and a barrier plate assembly including a plurality of barrier plates that are disposed between the deposition source nozzle unit and the patterning slit sheet in the first direction and that partition a deposition space between the deposition source nozzle unit and the patterning slit sheet into a plurality of sub-deposition spaces. The thin film deposition apparatus and the substrate are spaced apart from each other. The thin film deposition apparatus or the substrate is moved relative to the other. The patterning slit sheet has a first alignment mark and a second alignment mark that are spaced apart from each other. The substrate has a first alignment pattern and a second alignment pattern that are disposed spaced apart from each other. The thin film deposition apparatus further includes a first camera assembly for photographing the first alignment mark and the first alignment pattern, and a second camera assembly for photographing the second alignment mark and the second alignment pattern.

The plurality of barrier plates may extend in the second direction substantially perpendicular to the first direction.

The barrier plate assembly may include a first barrier plate assembly including a plurality of first barrier plates, and a second barrier plate assembly including a plurality of second barrier plates.

The plurality of first barrier plates and the plurality of second barrier plates may extend in a second direction substantially perpendicular to the first direction.

The plurality of first barrier plates may be arranged to respectively correspond to the plurality of second barrier plates.

The deposition source may be spaced apart from the barrier plate assembly.

The barrier plate assembly may be spaced apart from the patterning slit sheet.

The first alignment pattern may include a plurality of first marks arranged in a third direction perpendicular to the first and second directions. The second alignment pattern may include a plurality of second marks arranged in the third direction. The first alignment pattern and the second alignment pattern may be spaced apart from each other in the first direction.

At least one of the first mark or the second mark may have a polygonal shape.

At least one of the first mark or the second mark may have a triangular shape.

The first alignment pattern and the second alignment pattern may be formed in the form of a saw tooth.

A direction in which the first camera assembly and the second camera assembly may be arranged is perpendicular to the first direction.

The first camera assembly and the second camera assembly may be disposed over the substrate to correspond to the first alignment mark and the second alignment mark, respectively.

The thin film deposition apparatus may further include a controller for determining a degree to which the substrate and the patterning slit sheet are aligned with each other, based on information captured by the first camera assembly and the second camera assembly.

The controller may determine the degree to which the substrate and the patterning slit sheet are aligned with each other in the first direction by comparing a first distance between images of the first alignment pattern and the first alignment mark photographed by the first camera assembly with a second distance between images of the second alignment pattern and the second alignment mark photographed by the second camera assembly.

The controller may determine whether the patterning slit sheet is tilted in a plane formed by the first and third directions and is misaligned to the substrate by comparing an image of the first alignment mark photographed by the first camera assembly with an image of the second alignment mark photographed by the second camera assembly.

The controller may determine that the patterning slit sheet is tilted within the plane formed by the first and third directions towards the second alignment mark when a width of the image of the first alignment mark is greater than a width of the image of the second alignment mark, and may determine that the patterning slit sheet is tilted within the plane formed by the first and third directions towards the first alignment mark when the width of the image of the first alignment mark is less than the width of the image of the second alignment mark.

The controller may determine whether the substrate is tilted within the plane formed by the first and third directions by comparing an image of the first alignment pattern photographed by the first camera assembly with an image of the second alignment pattern photographed by the second camera assembly.

The controller may determine that the substrate is tilted within the plane formed by the first and third directions towards the second alignment pattern when a width of the image of the first alignment pattern is greater than a width of the image of the second alignment pattern, and may determine that the substrate is tilted within the plane formed by the first and third directions towards the first alignment pattern when the width of the image of the first alignment pattern is less than the width of the image of the second alignment pattern.

The substrate and the patterning slit sheet may be aligned with each other by moving the substrate or the patterning slit sheet, based on the degree of alignment, determined by the controller.

Another aspect of embodiments according to the present invention provides a method of manufacturing an organic light-emitting display device by using a thin film deposition apparatus for forming a thin film on a substrate. The method includes: arranging the substrate to be separated and spaced apart from the thin film deposition apparatus by a distance; depositing a deposition material discharged from the thin film deposition apparatus onto the substrate while the thin film deposition apparatus or the substrate is moved relative to the other; and aligning the thin film deposition apparatus with the substrate while the thin film deposition apparatus or the substrate is moved relative to the other.

The depositing of the deposition material on the substrate may include continuously depositing the deposition material discharged from the thin film deposition apparatus on the substrate while the substrate is moved relative to the thin film deposition apparatus.

The aligning of the thin film deposition apparatus with the substrate may include photographing an alignment mark on the substrate and an alignment pattern on the thin film deposition apparatus by using a camera assembly; determining a degree to which the substrate and the thin film deposition apparatus are aligned to each other by comparing images of the alignment mark and alignment pattern photographed by the camera assembly; and aligning the substrate and the thin film deposition apparatus with each other by moving the substrate or the thin film deposition apparatus, based on the degree of alignment.

### BRIEF DESCRIPTION OF THE DRAWINGS

A more complete appreciation of the invention, and many of the aspects thereof, will be readily apparent as the same becomes better understood by reference to the following detailed description when considered in conjunction with the accompanying drawings in which like reference symbols indicate the same or similar components, wherein:

FIG. 1 illustrates a thin film deposition system that includes a thin film deposition apparatus constructed as an embodiment of the present invention;

FIG. 2 illustrates a modified example of the thin film deposition system of FIG. 1;

FIG. 3 is a schematic oblique view of a thin film deposition apparatus according to an embodiment of the present invention;

FIG. 4 is a schematic side sectional view of the thin film deposition apparatus of FIG. 3;

FIG. 5 is a schematic sectional view of the thin film deposition apparatus of FIG. 3 in an X-Z plane;

FIG. 6 is a plan view illustrating arrangement of a substrate and a patterning slit sheet of FIG. 3, according to an embodiment of the present invention;

FIG. 7 illustrates an arrangement of first and second alignment patterns and first and second alignment marks when the substrate and the patterning slit sheet of FIG. 3 are aligned appropriately with each other, according to an embodiment of the present invention;

FIG. 8 illustrates an arrangement of the first and second alignment patterns and the first and second alignment marks when the substrate of FIG. 3 is moved in a negative X-axis direction;

FIG. 9 illustrates an arrangement of the first and second alignment patterns and the first and second alignment marks when the substrate of FIG. 3 is distorted in a direction indicated by an arrow θ, according to an embodiment of the present invention;

FIG. 10 is a schematic oblique view of a thin film deposition apparatus constructed as another embodiment of the present invention;

FIG. 11 is a schematic oblique view of a thin film deposition apparatus constructed as another embodiment of the present invention;

FIG. 12 is a schematic oblique view of a thin film deposition apparatus constructed as another embodiment of the present invention;

FIG. 13 is a schematic side cross-sectional view of the thin film deposition apparatus of FIG. 12;

FIG. 14 is a schematic sectional view of the thin film deposition apparatus of FIG. 12 in an X-Z plane;

FIG. 15 is a schematic oblique view of a thin film deposition apparatus constructed as another embodiment of the present invention; and

FIG. 16 is a cross-sectional view of an active matrix organic light-emitting display device manufactured by using a thin film deposition apparatus, according to an embodiment of the present invention.

### DETAILED DESCRIPTION

Hereinafter, exemplary embodiments of the present invention will now be described more fully with reference to the accompanying drawings. In the drawings, the thicknesses of layers and regions are exaggerated for clarity. Like reference numerals in the drawings denote like elements, and thus redundant descriptions may be omitted.

An organic light-emitting display device may include intermediate layers, and intermediate layers may include an emission layer disposed between a first electrode and a second electrode with the first and second electrodes being arranged opposite to each other. The electrodes and the intermediate layers may be formed via various methods, one of which may be a separate deposition method. When an organic light-emitting display device is manufactured by using the deposition method, a fine metal mask (FMM) having the same pattern as a thin film to be formed is disposed to closely contact a substrate, and a thin film material is deposited over the FMM in order to form the thin film having the desired pattern.

Such deposition method using such a FMM is however not suitable for manufacturing larger devices using a large mother glass (e.g., a mother glass having a size of 5 G or greater). In other words, when such a large mask is used, the mask may bend due to its own weight, thereby distorting a pattern. This is not conducive for the recent trend towards high-definition patterns.

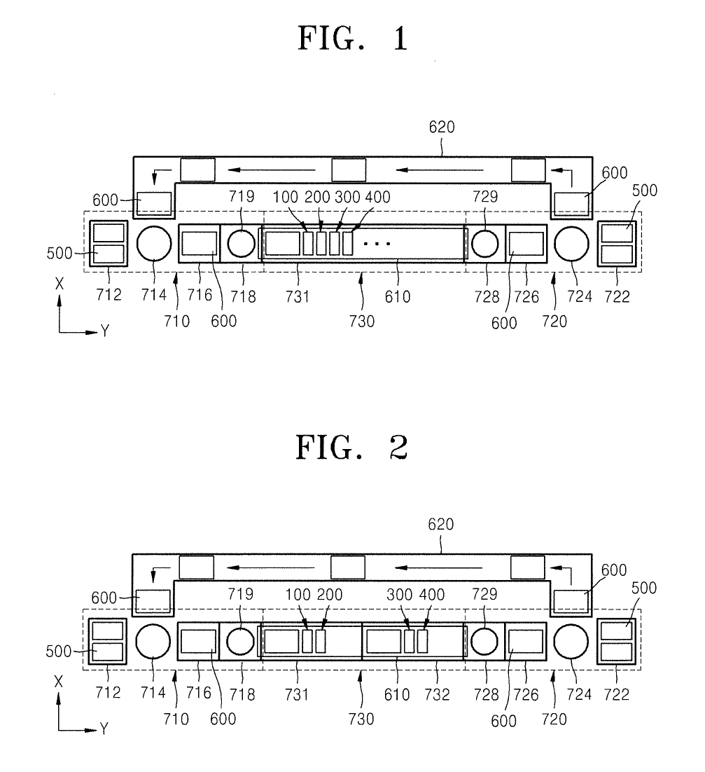

FIG. 1 illustrates a thin film deposition system that includes a thin film deposition apparatus constructed as an embodiment of the present invention. FIG. 2 illustrates a modified example of the thin film deposition apparatus of FIG. 1.

Referring to FIG. 1, the thin film deposition system includes a loading unit 710, a deposition unit 730, an unloading unit 720, a first conveyer unit 610, and a second conveyer unit 620.

The loading unit 710 includes a first rack 712, a transport robot 714, a transport chamber 716, and a first inversion chamber 718.

A plurality of substrates 500 onto which a deposition material is not applied are stacked up on the first rack 712. The transport robot 714 picks up one of the substrates 500 from the first rack 712, disposes the substrate 500 on an electrostatic chuck 600 transferred by the second conveyor unit 620, and moves the electrostatic chuck 600 having the substrate 500 thereon into the transport chamber 716.

The first inversion chamber 718 is disposed adjacent to the transport chamber 716. The first inversion chamber 718 includes a first inversion robot 719 that inverts the electrostatic chuck 600 and then loads the electrostatic chuck 600 into the first conveyer unit 610 of the deposition unit 730.

Referring to FIG. 1, the transport robot 714 places one of the substrates 500 on the surface of the electrostatic chuck 600, and the electrostatic chuck 600 having the substrate 500 thereon is loaded into the transport chamber 716. Then, the first inversion robot 719 inverts the electrostatic chuck 600 in such a manner that the substrate 500 is turned upside down in the deposition unit 730.

The unloading unit 720 is constituted to operate in an opposite manner in comparison with the loading unit 710 described above. Specifically, a second inversion robot 729 in a second inversion chamber 728 inverts the electrostatic chuck 600 having the substrate 500 thereon, which has passed through the deposition unit 730, and then moves the electrostatic chuck 600 having the substrate 500 thereon into an ejection chamber 726. Then, an ejection robot 724 removes the electrostatic chuck 600 having the substrate 500 thereon from the ejection chamber 726, separates the substrate 500 from the electrostatic chuck 600, and then loads the substrate 500 onto the second rack 722. The electrostatic chuck 600 separated from the substrate 500 is returned back into the loading unit 710 via the second conveyer unit 620.

However, the present invention is not limited to the above description. For example, when disposing the substrate 500 on the electrostatic chuck 600, the substrate 500 may be fixed onto a bottom surface of the electrostatic chuck 600 and then moved into the deposition unit 730. In this case, for example, the first inversion chamber 718 and the first inversion robot 719, and the second inversion chamber 728 and the second inversion robot 729 are not required.

The deposition unit 730 may include at least one deposition chamber. As illustrated in FIG. 1, according to the described embodiment, the deposition unit 730 includes a first chamber 731, in which first to four thin film deposition apparatuses 100, 200, 300, and 400 are disposed. Although FIG. 1 illustrates that a total of four thin film deposition apparatuses, i.e., the first through fourth thin film deposition apparatuses 100 through 400, are installed in the first chamber 731, the total number of thin film deposition apparatuses that are to be installed in the first chamber 731 may vary according to a deposition material and deposition conditions. The first chamber 731 may be maintained in a vacuum state during a deposition process.

Referring to FIG. 2, in a thin film deposition apparatus constructed with another embodiment of the present invention, a deposition unit 730 may include a first chamber 731 and a second chamber 732 that are connected to each other. In this case, first and second thin film deposition apparatuses 100 and 200 may be disposed in the first chamber 731, and third and fourth thin film deposition apparatuses 300 and 400 may be disposed in the second chamber 732. In other embodiments, more than two chambers may be used.

Referring to FIG. 1, in the current embodiment, the electrostatic chuck 600 having the substrate 500 thereon may be moved to at least the deposition unit 730 and particularly, may be sequentially moved to the loading unit 710, the deposition unit 730, and the unloading unit 720 via the first conveyor unit 610. Then, the electrostatic chuck 600 is separated from the substrate 500 by the unloading unit 720, and is returned back to the loading unit 710 via the second conveyor unit 620.

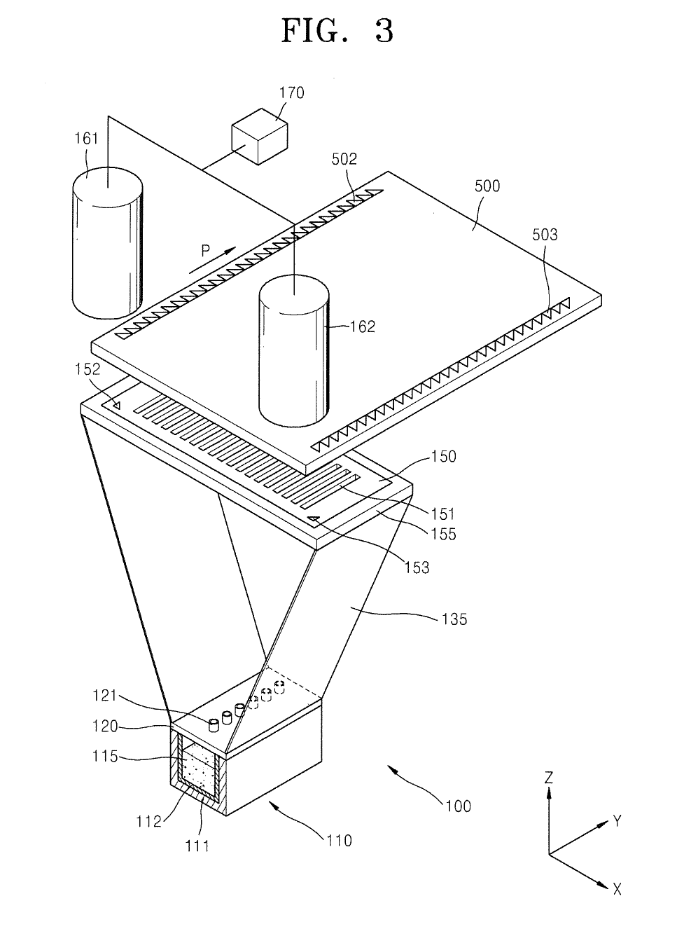

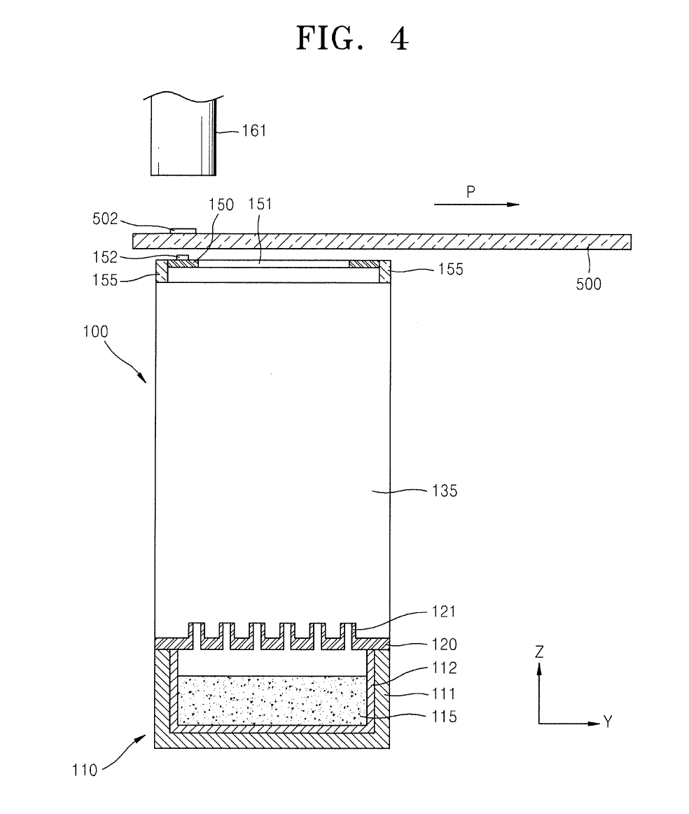

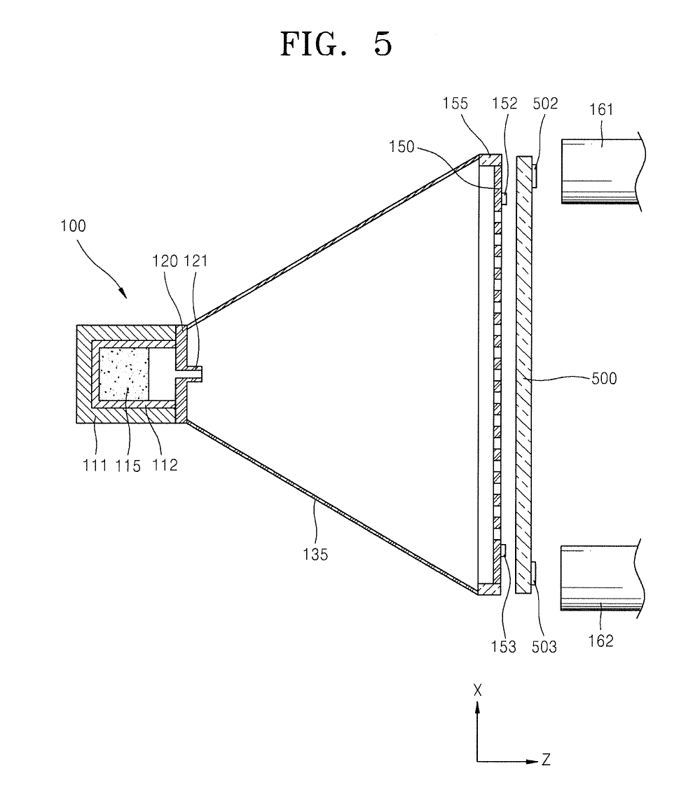

FIG. 3 is a schematic perspective view of a thin film deposition apparatus 100 constructed with an embodiment of the present invention. FIG. 4 is a schematic side sectional view of the thin film deposition apparatus 100 of FIG. 3. FIG. 5 is a schematic sectional view of the thin film deposition apparatus 100 of FIG. 3.

Referring to FIGS. 3 through 5, the thin film deposition apparatus 100 includes a deposition source 110, a deposition source nozzle unit 120, a patterning slit sheet 150, a first camera assembly 161, a second camera assembly 162, and a controller 170.

Specifically, the first chamber 731 of FIG. 1 may be basically maintained in a high-vacuum state as in a deposition method using a fine metal mask (FMM) so that a deposition material 115 emitted from the deposition source 110 and discharged through the deposition source nozzle unit 120 and the patterning slit sheet 150 may be deposited onto a substrate 500 in a desired pattern. In addition, the temperature of the patterning slit sheet 150 may be sufficiently lower than the temperature of the deposition source 110. In this regard, the temperature of the patterning slit sheet 150 may be about 100° C. or less. The temperature of the patterning slit sheet 150 may be sufficiently low so as to reduce thermal expansion of the patterning slit sheet 150.

The substrate 500 that is a deposition target substrate may be disposed in the first chamber 731. The substrate 500 may be a substrate for flat panel displays. A large substrate, such as a mother glass, for manufacturing a plurality of flat panel displays, may be used as the substrate 500. Other substrates may also be employed.

In particular, in the contemporary FMM deposition method, the size of the FMM is equal to the size of a substrate. Thus, since the size of the FMM has to be increased as the substrate becomes larger, it is neither straightforward to manufacture a large FMM nor to extend an FMM to be accurately aligned with a pattern.

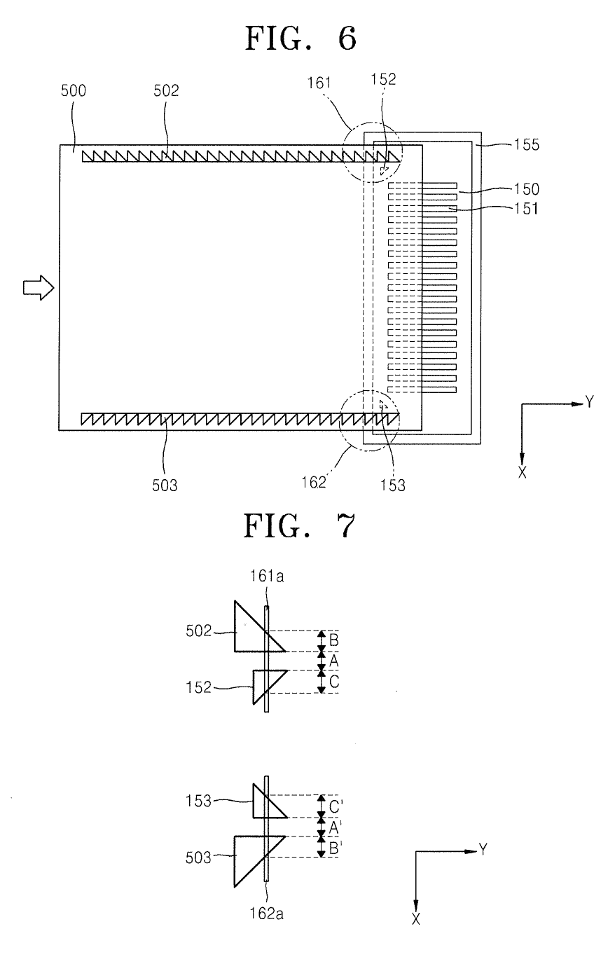

In order to solve this problem, in the thin film deposition apparatus 100, deposition may be performed while the thin film deposition apparatus 100 or the substrate 500 is moved relative to the other. In other words, deposition may be continuously performed while the substrate 500, which is disposed such as to face the thin film deposition apparatus 100, is moved in a Y-axis direction. In other words, deposition may be performed in a scanning manner while the substrate 500 is moved in a direction (first direction) indicated by an arrow R in FIG. 6.

In the thin film deposition apparatus 100 constructed as the current embodiment, the patterning slit sheet 150 may be significantly smaller than a FMM used in a conventional deposition method. In other words, in the thin film deposition apparatus 100, deposition is continuously performed, i.e., in a scanning manner while the substrate 500 is moved in the Y-axis direction. Thus, lengths of the patterning slit sheet 150 in the X-axis and Y-axis directions may be less (e.g., significantly less) than the lengths of the substrate 500 in the X-axis and Y-axis directions. As described above, since the patterning slit sheet 150 may be formed to be smaller (e.g., significantly smaller) than the FMM used in the conventional deposition method, it is relatively easy to manufacture the patterning slit sheet 150. That is, using the patterning slit sheet 150, which is smaller than the FMM used in the conventional deposition method, is more convenient in all processes, including etching and other subsequent processes, such as precise extension, welding, moving, and cleaning processes, compared to the conventional deposition method using the larger FMM. This is more advantageous for a relatively large display device.

The deposition source 110 that contains and heats the deposition material 115 is disposed at an opposite side of the first chamber 731 to a side at which the substrate 500 is disposed. The deposition source 110 is disposed opposite to the substrate 500, and the deposition source 110 is disposed at one side of the first chamber 710 with the one side being disposed opposite to the substrate 500. While the deposition material 115 contained in the deposition source 110 is vaporized, the deposition material 115 may be deposited onto the substrate 500.

In particular, the deposition source 110 includes a crucible 112 that is filled with the deposition material 115, and a cooling block 111 that heats the crucible 112 to vaporize the deposition material 115 contained in the crucible 112 towards a side of the crucible 111, and in particular, towards the deposition source nozzle unit 120. The cooling block 111 prevents radiation of heat from the crucible 112 outside, i.e., into the first chamber 731, and may thus include a heater (not shown) for heating the crucible 112.

The deposition source nozzle unit 120 is disposed at a side of the deposition source 110, and in particular, at the side of the deposition source 110 facing the substrate 500. The deposition source nozzle unit 120 includes a plurality of deposition source nozzles 121 that may be arranged at equal intervals in the Y-axis direction, i.e., a scanning direction of the substrate 500. The deposition material 115 that is vaporized in the deposition source 110, passes through the deposition source nozzle unit 120 towards the substrate 500. As described above, when the deposition source nozzle unit 120 includes the plurality of deposition source nozzles 121 arranged in the Y-axis direction, that is, the scanning direction of the substrate 500, the size of a pattern formed of the deposition material 115 discharged through the patterning slits 151 of the patterning slit sheet 150 is affected only by the size of one of the deposition source nozzles 121 (since there is only one line of deposition nozzles in the X-axis direction). Thus, no shadow zone may be formed on the substrate 500. In addition, since the plurality of deposition source nozzles 121 are arranged in the scanning direction (Y-axis direction) of the substrate 500, even though there may be a difference in flux between the deposition source nozzles 121, such difference may be compensated for and deposition uniformity may be maintained constant.

The patterning slit sheet 150 and a frame 155 are disposed between the deposition source 110 and the substrate 500. The frame 155 may be formed in a lattice shape, similar to a window frame. The patterning slit sheet 150 is bound inside the frame 155. The patterning slit sheet 150 has a plurality of patterning slits 151 arranged in the X-axis direction. The plurality of patterning slits 151 may be linearly arranged in the X-axis direction. The deposition material 115 that is vaporized in the deposition source 110, passes through the deposition source nozzle unit 120 and the patterning slit sheet 150 towards the substrate 500. The patterning slit sheet 150 may be manufactured by etching, which is the same method as used in a contemporary method of manufacturing an FMM, and in particular, a striped FMM. In this regard, the total number of patterning slits 151 may be greater than the total number of deposition source nozzles 121.

In addition, the deposition source 110 and the deposition source nozzle unit 120 coupled to the deposition source 110 may be separated and spaced apart from the patterning slit sheet 150 by a distance (e.g., a predetermined distance). Alternatively, the deposition source 110 and the deposition source nozzle unit 120 coupled to the deposition source 110 may be connected to the patterning slit sheet 150 by connection units 135. That is, the deposition source 110, the deposition source nozzle unit 120, and the patterning slit sheet 150 may be integrally formed as a single body by being connected to each other via the connection units 135. The connection units 135 may guide the vaporized deposition material 115, which is discharged through the deposition source nozzles 121, to move straight and not to flow in the X-axis direction. Referring to FIG. 3, the connection units 135 may be formed on left and right sides of the deposition source 110, the deposition source nozzle unit 120, and the patterning slit sheet 150 to guide the deposition material 115 not to flow in the X-axis direction; however, aspects of the present invention are not limited thereto. For example, the connection units 135 may be formed in the form of a sealed box so as to guide the deposition material 115 to not flow in both the X-axis and Y-axis directions.

As described above, the thin film deposition apparatus 100 constructed as the current embodiment performs deposition while being moved relative to the substrate 500. In order to move the thin film deposition apparatus 100 relative to the substrate 500, the patterning slit sheet 150 is separated and spaced apart from the substrate 500 by a distance (e.g., a predetermined distance).

In particular, in a contemporary deposition method using a FMM, deposition is performed with the FMM in close contact with a substrate in order to prevent formation of a shadow zone on the substrate. When the FMM is used in close contact with the substrate, however, the contact may cause defects. In addition, in the contemporary deposition method, the size of the mask is the same as the size of the substrate since the mask cannot be moved relative to the substrate. Thus, the size of the mask has to be increased as display devices become larger. It is however not easy to manufacture such a large mask.

In order to solve this problem, in the thin film deposition apparatus 100 constructed as the current embodiment, the patterning slit sheet 150 may be disposed to be separated from the substrate 500 by a distance (e.g., a predetermined distance).

As described above, in accordance with embodiments of the present invention, a mask may be formed to be smaller than a substrate, and deposition is performed while the mask is moved relative to the substrate. Thus, the mask may be easily manufactured. In addition, defects caused due to the contact between a substrate and a FMM, which occur in the contemporary deposition method, may be prevented. Furthermore, since it is unnecessary to dispose the FMM in close contact with the substrate during a deposition process, the manufacturing time may be reduced.

In an embodiment of the present invention, the thin film deposition apparatus 100 further includes first and second alignment patterns 502 and 503, first and second alignment marks 152 and 153, first and second camera assemblies 161 and 162, and a controller 170 so as to align the substrate 500 and the patterning slit sheet 150 with each other.

The first and second alignment patterns 502 and 503 are foil led on the substrate 500 in a moving direction P of the substrate 500. The first and second alignment patterns 502 and 520 may be formed at respective ends of the substrate 500 to be spaced apart from each other. The first alignment pattern 502 may include a plurality of first marks 502a arranged in the moving direction P of the substrate 500, and the second alignment pattern 503 may include a plurality of second marks 503a arranged in the moving direction P of the substrate 500. The first and second marks 502a and 503a may have a polygonal shape, e.g., a right triangle shape as illustrated in FIG. 3. If each of the first and second marks 502a and 503a has a right triangle shape, then an oblique side of the right triangle may be disposed to face edges of the substrate 500 as illustrated in FIG. 3. In this case, the first and second alignment patterns 502 and 503 may be formed in the form of a saw tooth.

The first and second alignment marks 152 and 153 may be disposed at respective ends of the patterning slit sheet 150. In an embodiment, the first and second alignment marks 152 and 153 may be disposed at corners of the patterning slit sheet 150. The first and second alignment marks 152 and 153 may be disposed at two adjacent corners of the patterning slit sheet 150. The first and second alignment marks 152 and 153 may be spaced apart from each other in a direction (a second direction) perpendicular to the moving direction P. The first and second alignment marks 152 and 153 may have a polygonal shape, e.g., a right triangle shape as illustrated in FIG. 3. If each of the first and second alignment marks 152 and 153 has a right triangle shape, then an oblique side thereof may be disposed to face the patterning slits 151 as illustrated in FIG. 3.

If the substrate 500 and the patterning slit sheet 150 are appropriately aligned with each other, then the first and second alignment marks 152 and 153 are disposed between the first and second alignment patterns 502 and 503. This will be described later.

The first and second camera assemblies 161 and 162 may be disposed on the substrate 500 to correspond to the first and second alignment marks 152 and 153, respectively. The first camera assembly 161 may photograph the first alignment pattern 502 and the first alignment mark 152 on the substrate 500, and the second camera assembly 162 may photograph the second alignment pattern 503 and the second alignment mark 153 on the substrate 500. Since the substrate 500 may be transparent, the first and second camera assemblies 161 and 162 may photograph the first and second alignment marks 152 and 153, viewed through the substrate 500, respectively. A direction in which the first and second camera assemblies 161 and 162 are aligned may be the second direction perpendicular to the moving direction P.

The controller 170 may determine a degree in which the substrate 500 and the patterning slit sheet 150 are aligned to each other by analyzing information captured by the first and second camera assemblies 161 and 162, and may move the substrate 500 or the patterning slit sheet 150 based on the degree of alignment.

Alignment of the substrate 500 with the patterning slit sheet 150 illustrated in FIG. 3 will now be described with reference to FIGS. 6 through 9.

FIG. 6 is a plan view illustrating arrangement of the substrate 500 and the patterning slit sheet 150 of FIG. 3, viewed from first and second camera assemblies 161 and 162, according to an embodiment of the present invention.

Referring to FIGS. 3 and 6, the substrate 500 is moved in a Y-axis direction. The first and second alignment patterns 502 and 503 are disposed in parallel with the Y-axis direction in which the substrate 500 is moved. The first and second alignment patterns 502 and 503 may be disposed at respective ends of the substrate 500, while being spaced apart from each other in an X-axis direction (second direction) perpendicular to the Y-axis direction.

The first and second alignment marks 152 and 153 disposed on the patterning slit sheet 150 may be spaced apart from each other in the second direction, and may be disposed between the first and second alignment patterns 502 and 503.

In an embodiment, the distance between the first and second alignment patterns 502 and 503 may be larger than the distance between first and second alignment marks 152 and 153.

FIG. 7 illustrates an arrangement of the first and second alignment patterns 502 and 503 and the first and second alignment marks 152 and 153 when the substrate 500 and the patterning slit sheet 150 of FIG. 6 are aligned appropriately with each other, according to an embodiment of the present invention.

Referring to FIGS. 6 and 7, an imaging device 161a of the first camera assembly 161 and an imaging device 162a of the second camera assembly 162 are disposed in a second direction (X-axis direction) so as to photograph the first alignment pattern 502 and the alignment mark 152, and the alignment pattern 503 and the second alignment mark 153, respectively. When the substrate 500 and the patterning slit sheet 150 are appropriately aligned with each other, then a distance A between the first alignment pattern 502 and the first alignment mark 152 is equal to a distance A′ between the second alignment pattern 503 and the second alignment mark 153. Also, in this case, a width B of an image of the first alignment pattern 502 photographed by the first camera assembly 161 is equal to a width B′ of an image of the second alignment pattern 503 photographed by the camera assembly 162. Also, a width C of an image of the first alignment mark 152 photographed by the first camera assembly 161 is equal to a width C′ of an image of the second alignment mark 153 photographed by the camera assembly 162.

In an embodiment, when the substrate 500 and the patterning slit sheet 150 are appropriately aligned with each other, a distance A between the first alignment pattern 502 and the first alignment mark 152 may be equal to a distance A′ between the second alignment pattern 503 and the second alignment mark 153. In this case, a width B of an image of the first alignment pattern 502 photographed by the imaging device 161a of the first camera assembly 161 may be equal to a width B′ of an image of the second alignment pattern 503 concurrently (e.g., simultaneously) photographed by the imaging device 162a of the camera assembly 162. Also, a width C of an image of the first alignment mark 152 photographed by the imaging device 161a of the first camera assembly 161 may be equal to a width C′ of an image of the second alignment mark 153 concurrently (e.g., simultaneously) photographed by the imaging device 162a of the camera assembly 162.

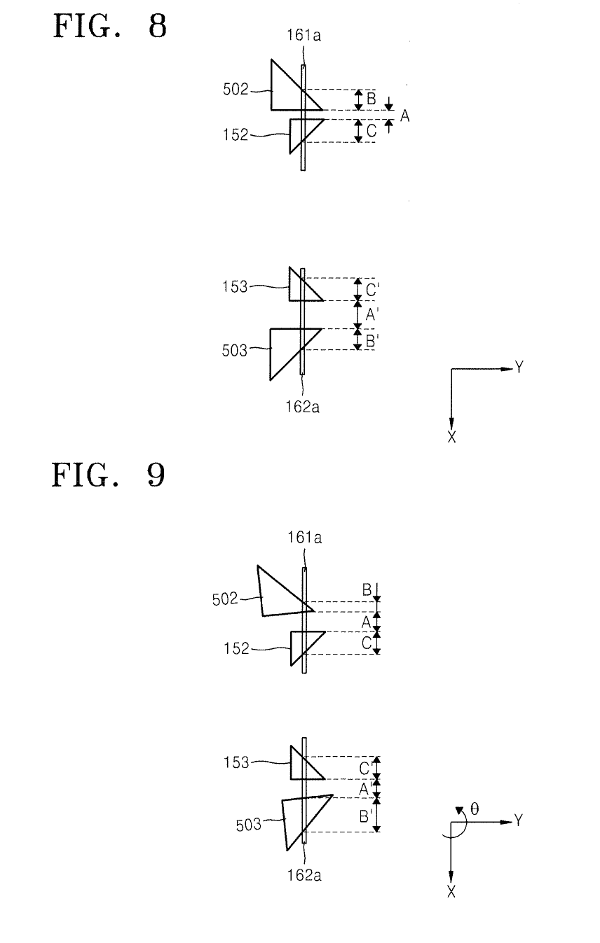

FIG. 8 illustrates an arrangement of the first and second alignment patterns 502 and 503 and the first and second alignment marks 152 and 153 when the substrate 500 of FIG. 6 is moved in a negative X-axis direction, according to an embodiment of the present invention.

Referring to FIGS. 6 and 8, when the substrate 500 is moved in the negative X-axis direction, a distance A between the first alignment pattern 502 and the first alignment mark 152 is less than a distance A′ between the second alignment pattern 503 and the second alignment mark 153. However, in this case, a width B of an image of the first alignment pattern 502 photographed by first camera assembly 161 is equal to a width B′ of an image of the second alignment pattern 503 photographed by the camera assembly 162, and a width C of the first alignment mark 152 photographed by the first camera assembly 161 is equal to a width C′ of the second alignment mark 153 photographed by the camera assembly 162.

If the substrate 500 has been moved in the negative x-axis direction, the controller 170 controls a driving unit (not shown) to move substrate 500 by a distance (A′-A)/2 in an X-axis direction.

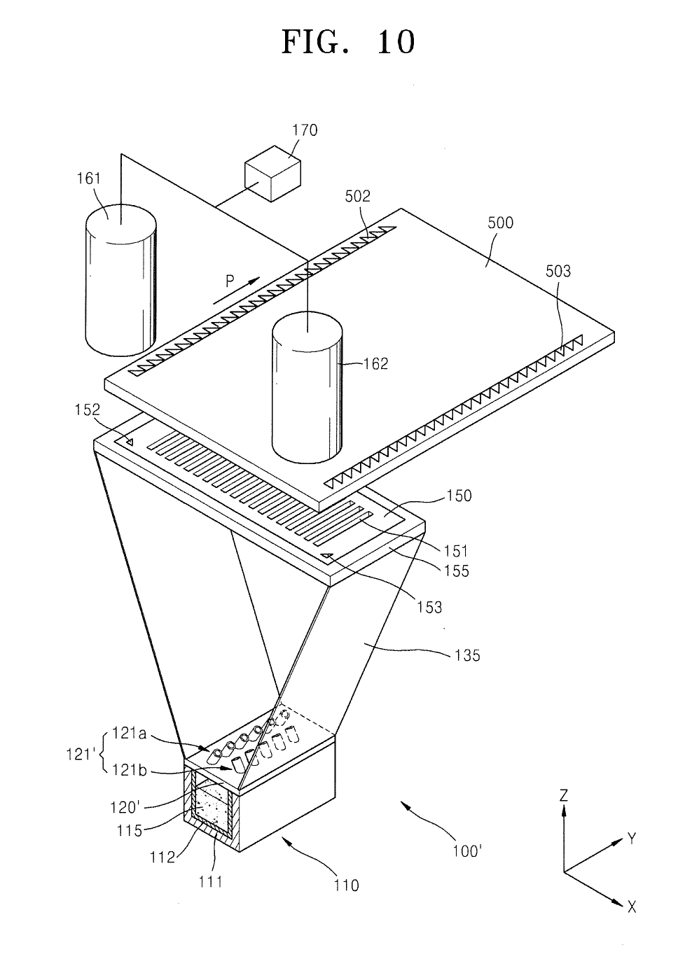

FIG. 9 illustrates an arrangement of the first and second alignment patterns 502 and 503 and the first and second alignment marks 152 and 153 when the substrate 500 of FIG. 6 is distorted in a direction indicated by an arrow θ (e.g., rotated by an angle θ), according to an embodiment of the present invention. If the substrate 500 is distorted in the direction θ with respect to the patterning slit sheet 150, it means that the substrate 500 is moved counterclockwise (in the direction θ) or clockwise (in a negative direction −θ) with respect to the Z-axis.

Referring to FIG. 9, if the substrate 500 is distorted (e.g., rotated) in the direction θ (counterclockwise), then a width C of an image of the first alignment mark 152 photographed by the first camera assembly 161 is equal to a width C′ of an image of the second alignment mark 153 photographed by the second camera assembly 162, but a width B of the first alignment pattern 502 photographed by the first camera assembly 161 is less than a width B′ of the second alignment pattern 503 photographed by the second camera assembly 162. The degree to which the substrate 500 is distorted (e.g., rotated) is equal to Arctan((B′-B)/A). In this case, in order to align the substrate 500 with the patterning slit sheet 150, the controller 170 of FIG. 3 controls a driving unit (not shown) to move (e.g., rotate) the substrate 500 by an angle of Arctan((B′-B)/A) in the negative direction −θ (clockwise).

Although not shown, if the patterning slit sheet 150 is distorted in the direction θ (counterclockwise), then a width C of an image of the first alignment mark 152 photographed by the first camera assembly 161 is less than a width C′ of an image of the second alignment mark 153 photographed by the camera assembly 162. In this case, the controller 170 controls the driving unit to move (e.g., rotate) the patterning slit sheet 150 by an angle of Arctan((C′-C)/A) in the negative direction of the arrow −θ (clockwise).

As described above, the thin film deposition apparatus 100 of FIG. 3 according to an embodiment of the present invention is capable of controlling alignment of the substrate 500 with the patterning slit sheet 150 not only when the substrate 500 is moved in a direction (second direction) perpendicular to a moving direction (first direction) but also when the substrate 500 is distorted (e.g., rotated) with respect to the moving direction P (first direction).

FIG. 10 is a schematic perspective view of a thin film deposition apparatus 100′ according to another embodiment of the present invention. Referring to FIG. 10, the thin film deposition apparatus 100′ includes a deposition source 110, a deposition source nozzle unit 120′, and a patterning slit sheet 150. The deposition source 110 includes a crucible 112 that is filled with a deposition material 115, and a cooling block 111 that heats the crucible 112 to vaporize the deposition material 115 contained in the crucible 112, so as to move the vaporized deposition material 115 toward the deposition source nozzle unit 120′. The deposition source nozzle unit 120′, which has a planar shape, is disposed at a side of the deposition source 110. The deposition source nozzle unit 120′ includes a plurality of deposition source nozzles 121′ arranged in the Y-axis direction. The patterning slit sheet 150 and a frame 155 are disposed between the deposition source 110 and a substrate 500. The patterning slit sheet 150 has a plurality of patterning slits 151 arranged in the X-axis direction. The deposition source 110 and the deposition source nozzle unit 120′ may be connected to the patterning slit sheet 150 by connection units 135.

In the current embodiment, the plurality of deposition source nozzles 121′ formed on the deposition source nozzle unit 120′ are tilted at an angle (e.g., a predetermined angle), unlike the thin film deposition apparatus 100 of FIG. 3. In particular, the deposition source nozzles 121′ may include deposition source nozzles 121a and 121b arranged in respective rows. The deposition source nozzles 121a and 121b may be arranged in respective rows to alternate in a zigzag pattern. The deposition source nozzles 121a and 121b may be tilted at an angle (e.g., a predetermined angle) with respect to an XZ plane. The deposition source nozzles 121a and 121b may be formed not perpendicular to the XZ plane.

In the current embodiment, the deposition source nozzles 121a and 121b are arranged to tilt at an angle (e.g., a predetermined angle) with respect to each other. The deposition source nozzles 121a in a first row and the deposition source nozzles 121b in a second row may tilt to face each other. The first row of the deposition source nozzles 121a may tilt towards the second row of the deposition source nozzle of the deposition source nozzle 121b. That is, the top portions of the deposition source nozzles 121a of the first row disposed in a left part of the deposition source nozzle unit 120′ may be arranged to face towards a right side portion of the patterning slit sheet 150, and the top portions of the deposition source nozzles 121b of the second row in a right part of the deposition source nozzle unit 120′ may be arranged to face towards a left side portion of the patterning slit sheet 150.

Accordingly, a deposition rate of the deposition material 115 may be adjusted to lessen the difference between thicknesses of thin films formed on center and end portions of the substrate 500, thereby improving thickness uniformity. Moreover, utilization efficiency of the deposition material 115 may also be improved.

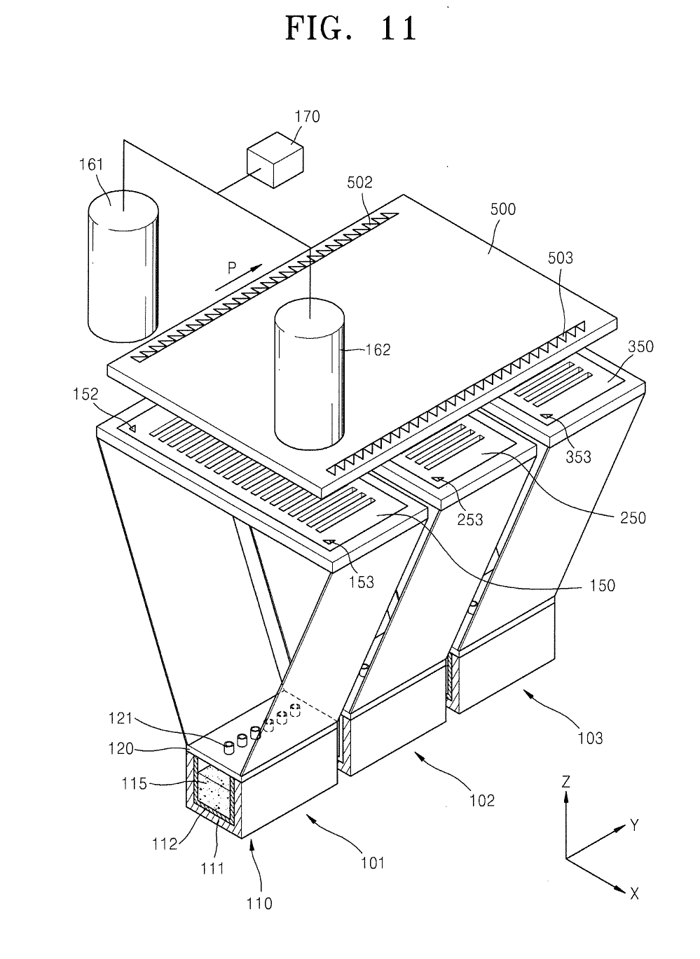

FIG. 11 is a schematic perspective view of a thin film deposition apparatus constructed as another embodiment of the present invention. Referring to FIG. 11, the thin film deposition apparatus according to the current embodiment may include a plurality of thin film deposition apparatuses, each of which has the structure of the thin film deposition apparatus 100 illustrated in FIG. 3. In other words, the thin film deposition apparatus according to the current embodiment may include a multi-deposition source that concurrently (e.g., simultaneously) discharges deposition materials for forming an R (red) emission layer, a G (green) emission layer, and a B (blue) emission layer.

In particular, the thin film deposition apparatus constructed as the current embodiment includes a first thin film deposition apparatus 101, a second thin film deposition apparatus 102, and a third thin film deposition apparatus 103. Each of the first thin film deposition apparatus 101, the second thin film deposition apparatus 102, and the third thin film deposition apparatus 103 has the same structure as the thin film deposition apparatus 100 described with reference to FIGS. 3 through 5, and thus a detailed description thereof will not be provided here.

The deposition sources 110 of the first thin film deposition apparatus 101, the second thin film deposition apparatus 102 and the third thin film deposition apparatus 103 may contain different deposition materials, respectively. The first thin film deposition apparatus 101 may contain a deposition material for forming the R emission layer, the second thin film deposition apparatus 102 may contain a deposition material for forming the G emission layer, and the third thin film deposition apparatus 103 may contain a deposition material for forming the B emission layer.

In other words, in a typical method of manufacturing an organic light-emitting display device, a separate chamber and mask may be generally used to form each color emission layer. However, when the thin film deposition apparatus constructed as the current embodiment is used, the R emission layer, the G emission layer and the B emission layer may be formed concurrently (e.g., at the same time) with a single multi-deposition source. Thus, time consumed to manufacture an organic light-emitting display device may be reduced (e.g., sharply reduced). In addition, the organic light-emitting display device may be manufactured with a reduced number of chambers, so that equipment costs may also be reduced (e.g., markedly reduced).

Although not illustrated, a patterning slit sheet 150 of the first thin film deposition apparatus 101, a patterning slit sheet 250 of the second thin film deposition apparatus 102, a patterning slit sheet 350 of the third thin film deposition apparatus 103 may be arranged to be offset by a constant distance with respect to each other, thereby preventing deposition regions corresponding to the patterning slit sheets 150, 250 and 350 from overlapping with one another on the substrate 500. In other words, when the first thin film deposition apparatus 102, the second thin film deposition apparatus 102, and the third thin film deposition apparatus 200 are used to deposit the R emission layer, the G emission layer, and the B emission layer, respectively, patterning slits 151 of the first thin film deposition apparatus 101, patterning slits 251 of the second thin film deposition apparatus 102, and patterning slits 351 of the second thin film deposition apparatus 300 are arranged not to be aligned with respect to each other, in order to form the R emission layer, the G emission layer, and the B emission layer in different regions of the substrate 500.

The deposition materials for forming the R emission layer, the G emission layer, and the B emission layer may be vaporized at different temperatures, respectively. Therefore, the temperatures of deposition sources of the respective first, second, and third thin film deposition apparatuses 101, 102, and 103 may be set to be different.

Although the thin film deposition apparatus according to the current embodiment includes three thin film deposition apparatuses, the present invention is not limited thereto. In other words, a thin film deposition apparatus according to another embodiment of the present invention may include a plurality of thin film deposition apparatuses, each of which contains a different deposition material. For example, a thin film deposition apparatus according to another embodiment of the present invention may include five thin film deposition apparatuses respectively containing materials for an R emission layer, a G emission layer, a B emission layer, an auxiliary layer (R′) of the R emission layer, and an auxiliary layer (G′) of the G emission layer.

As described above, a plurality of thin films may be formed concurrently (e.g., at the same time) with a plurality of thin film deposition apparatuses, and thus manufacturing yield and deposition efficiency may be improved. In addition, the overall manufacturing process is simplified, and the manufacturing costs may be reduced.

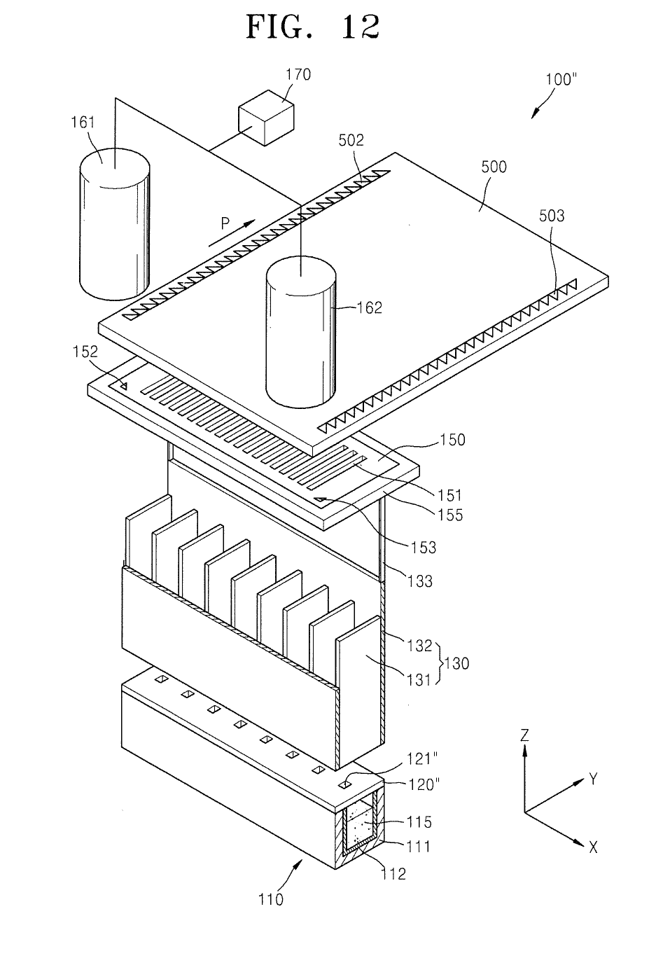

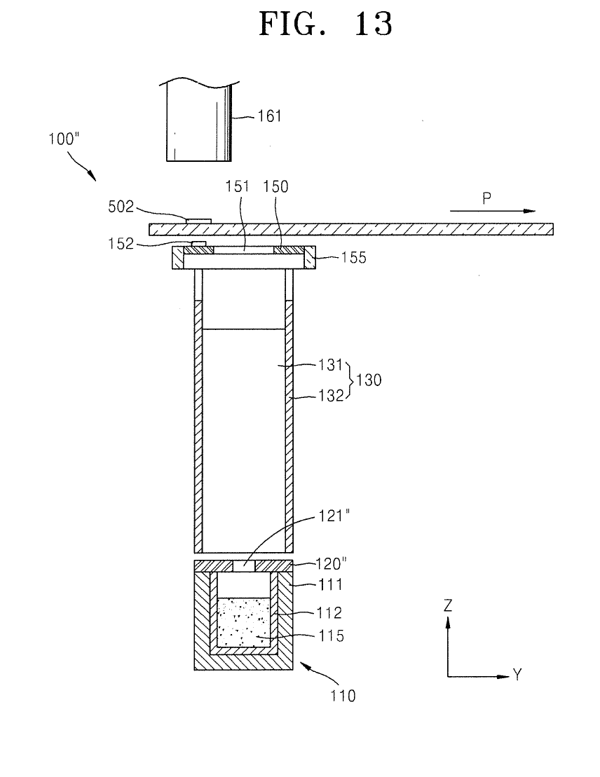

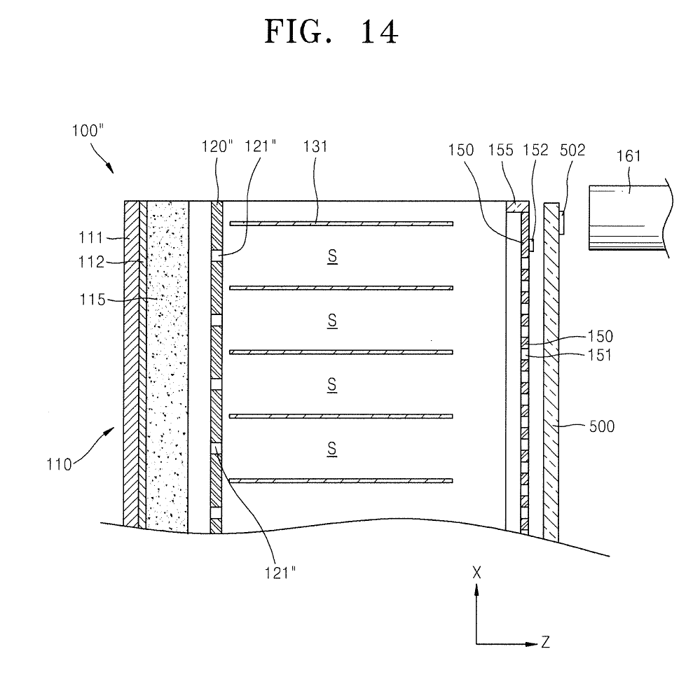

FIG. 12 is a schematic perspective view of a thin film deposition apparatus 100″ constructed as an embodiment of the present invention. FIG. 13 is a schematic side cross-sectional view of the thin film deposition apparatus 100″ of FIG. 12. FIG. 14 is a schematic sectional view of the thin film deposition apparatus 100″ of FIG. 12 in the X-Z plan.

Referring to FIGS. 12 through 14, the thin film deposition apparatus 100″ includes a deposition source 110, a deposition source nozzle unit 120″, a barrier plate assembly 130, and patterning slits 151.

Although a chamber is not illustrated in FIGS. 12 through 14 for the convenience of explanation, all the components of the thin film deposition apparatus 100″ may be disposed within a chamber that is maintained at an appropriate degree of vacuum. The chamber is maintained at an appropriate vacuum in order to allow a deposition material to move in a substantially straight line through the thin film deposition apparatus 100″.

In the chamber in which the thin film deposition apparatus 100″ is disposed, a substrate 500, which is a deposition target substrate, is transferred by the electrostatic chuck 600 of FIG. 1. The substrate 500 may be a substrate for flat panel display devices. A large substrate, such as a mother glass, for manufacturing a plurality of flat panel displays, may be used as the substrate 500. Other substrates may also be employed.

In an embodiment of the present invention, the substrate 500 may be moved relative to the thin film deposition apparatus 100″. For example, the substrate 500 may be moved in a direction of an arrow P, relative to the thin film deposition apparatus 100″.

Thus, as in the thin film deposition apparatus 100 of FIG. 3, a patterning slit sheet 150 included in the thin film deposition apparatus 100″ constructed as the current embodiment may be smaller (e.g., significantly smaller) than a FMM used in a typical deposition method. In other words, in the thin film deposition apparatus 100″ constructed as the current embodiment, deposition is continuously performed, i.e., in a scanning manner while the substrate 500 is moved in the Y-axis direction. Thus, a length of the patterning slit sheet 150 in the Y-axis direction may be less (e.g., significantly less) than a length of the substrate 500 provided a width of the patterning slit sheet 150 in the X-axis direction and a width of the substrate 500 in the X-axis direction are substantially equal to each other. However, even when the width of the patterning slit sheet 150 in the X-axis direction is less than the width of the substrate 500 in the X-axis direction, deposition may be performed on the entire substrate 500 in the scanning manner while the substrate 500 or the thin film deposition apparatus 100″ may be moved relative to the other.

As described above, since the patterning slit sheet 150 may be formed to be smaller (e.g., significantly smaller) than the FMM used in a typical deposition method, it is relatively easy to manufacture the patterning slit sheet 150. In other words, using the patterning slit sheet 150, which is smaller than the FMM used in the typical deposition method, is more convenient in all processes, including etching and other subsequent processes, such as precise extension, welding, moving, and cleaning processes, compared to the contemporary deposition method using the larger FMM. This is more advantageous for a relatively large display device.

The deposition source 110 that contains and heats a deposition material 115 is disposed at an opposite side of the chamber to a side in which the substrate 500 is disposed.

The deposition source 110 includes a crucible 112 that is filled with the deposition material 115, and a cooling block 111 surrounding the crucible 112. The cooling block 111 prevents radiation of heat from the crucible 112 outside, i.e., into the chamber. The cooling block 111 may include a heater (not shown) that heats the crucible 112.

The deposition source nozzle unit 120″ is disposed at a side of the deposition source 110, and in particular, at the side of the deposition source 110 facing towards the substrate 500. The deposition source nozzle unit 120″ includes a plurality of deposition source nozzles 121″ that may be arranged at equal intervals in the X-axis direction. The deposition material 115 that is vaporized in the deposition source 110 passes through the deposition source nozzles 121″ of the deposition source nozzle unit 120″ towards the substrate 500 that is a deposition target substrate.

The barrier plate assembly 130 is disposed at a side of the deposition source nozzle unit 120″. The barrier plate assembly 130 includes a plurality of barrier plates 131, and a barrier plate frame 132 that covers sides of the barrier plates 131. In other words, the barrier plate frame 132 in the embodiment of FIG. 12 includes two opposing barrier frame plates that are spaced from each other along the Y-axis direction with the barrier plates 131 located therebetween. While the barrier frame plate on the left side in FIG. 12 appears as being less in height than the one on the right side, they may have the same height as illustrated in FIG. 13. The plurality of barrier plates 131 may be arranged parallel to each other at equal intervals in the X-axis direction. In addition, each of the barrier plates 131 may be arranged parallel to an YZ plane in FIG. 2 and FIG. 12, and may have a rectangular shape. The plurality of barrier plates 131 arranged as described above partition a deposition space between the deposition source nozzle unit 120″ and the patterning slit sheet 150 into a plurality of sub-deposition spaces S. In the thin film deposition apparatus 100″ constructed as the current embodiment, as illustrated in FIG. 14, the deposition space is divided by the barrier plates 131 into the sub-deposition spaces S that respectively correspond to the deposition source nozzles 121″ through which the deposition material 115 is discharged.

The barrier plates 131 may be respectively disposed between adjacent deposition source nozzles 121″. In other words, each of the deposition source nozzles 121″ may be disposed between two adjacent barrier plates 131. The deposition source nozzles 121″ may be respectively located at the midpoint between two adjacent barrier plates 131. However, the present invention is not limited to this structure. For example, a plurality of deposition source nozzles 121″ may be disposed between two adjacent barrier plates 131. In this case, the deposition source nozzles 121″ may be also respectively located at the midpoint between two adjacent barrier plates 131.

As described above, since the barrier plates 131 partition the deposition space between the deposition source nozzle unit 120″ and the patterning slit sheet 150 into the plurality of sub-deposition spaces S, the deposition material 115 discharged through each of the deposition source nozzles 121″ is not mixed with the deposition material 115 discharged through the other deposition source nozzles 121″, and passes through the patterning slits 151 so as to be deposited on the substrate 500. In other words, the barrier plates 131 guide the deposition material 115, which is discharged through the deposition source nozzles 121″, to move straight and not to flow in the X-axis direction.

As described above, the deposition material 115 is forced to move straight by installing the barrier plates 131, so that a smaller shadow zone may be formed on the substrate 500 compared to a case where no barrier plates are installed. Thus, the thin film deposition apparatus 100″ and the substrate 500 may be separated and spaced apart from each other by a distance (e.g., predetermined distance D). This will be described later in detail.

The barrier plate frame 132, which forms sides of the barrier plates 131, maintains the positions of the barrier plates 131, and guides the deposition material 115, which is discharged through the deposition source nozzles 121″, not to flow in the Y-axis direction.

The deposition source nozzle unit 120″ and the barrier plate assembly 130 may be separated and spaced apart from each other by a distance (e.g., predetermined distance). This may prevent heat radiated from the deposition source unit 110 from being conducted to the barrier plate assembly 130. However, aspects of the present invention are not limited to this. For example, an appropriate heat insulator (not shown) may be further disposed between the deposition source nozzle unit 120″ and the barrier plate assembly 130. In this case, the deposition source nozzle unit 120″ and the barrier plate assembly 130 may be bound together with the heat insulator therebetween.

In addition, the barrier plate assembly 130 may be constructed to be detachable from the thin film deposition apparatus 100″. In the thin film deposition apparatus 100″ constructed as the current embodiment of the present invention, the deposition space is enclosed by using the barrier plate assembly 130, so that the deposition material 115 that remains undeposited is mostly deposited within the barrier plate assembly 130. Thus, since the barrier plate assembly 130 is constructed to be detachable from the thin film deposition apparatus 100″, when a large amount of the deposition material 115 lies in the barrier plate assembly 130 after a long deposition process, the barrier plate assembly 130 may be detached from the thin film deposition apparatus 100″ and then placed in a separate deposition material recycling apparatus in order to recover the deposition material 115. Accordingly, a reuse rate of the deposition material 115 is increased, so that the deposition efficiency is improved, and thus the manufacturing costs may be reduced.

The patterning slit sheet 150 and a frame 155 are disposed between the deposition source 110 and the substrate 500. The frame 155 may be formed in a lattice shape, similar to a window frame. The patterning slit sheet 150 is bound inside the frame 155. The patterning slit sheet 150 has a plurality of patterning slits 151 arranged in the X-axis direction. Each of the patterning slits 151 extends in the Y-axis direction. The deposition material 115 that has been vaporized in the deposition source 110 and passed through the deposition source nozzle 121″ passes through the patterning slits 151 towards the substrate 500.

The patterning slit sheet 150 may be formed of a metal thin film. The patterning slit sheet 150 may be fixed to the frame 150 such that a tensile force may be exerted thereon. The patterning slits 151 may be formed by etching the patterning slit sheet 150 to a stripe pattern.

In the thin film deposition apparatus 100″ constructed as the current embodiment, the total number of patterning slits 151 may be greater than the total number of deposition source nozzles 121″. In addition, there may be a greater number of patterning slits 151 in comparison with the number of deposition source nozzles 121″ disposed between two adjacent barrier plates 131. The number of patterning slits 151 may be equal to the number of deposition patterns to be formed on the substrate 500.

The barrier plate assembly 130 and the patterning slit sheet 150 may be disposed to be separated from each other by a distance (e.g., a predetermined distance). Alternatively, the barrier plate assembly 130 and the patterning slit sheet 150 may be connected by second connection members 133. The temperature of the barrier plate assembly 130 may increase to 100° C. or higher due to the deposition source 110 whose temperature is high. Thus, in order to prevent the heat of the barrier plate assembly 130 from being conducted to the patterning slit sheet 150, the barrier plate assembly 130 and the patterning slit sheet 150 may be separated and spaced apart from each other by a distance (e.g., a predetermined distance).

As described above, the thin film deposition apparatus 100″ constructed as the current embodiment performs deposition while being moved relative to the substrate 500. In order to move the thin film deposition apparatus 100″ relative to the substrate 500, the patterning slit sheet 150 is separated from the substrate 500 by a distance (e.g., a predetermined distance D). In addition, in order to prevent the formation of a relatively large shadow zone on the substrate 500 when the patterning slit sheet 150 and the substrate 500 are separated and spaced apart from each other, the barrier plates 131 are arranged between the deposition source nozzle unit 120″ and the patterning slit sheet 150 to force the deposition material 115 to move in a straight direction. The size of the shadow zone that may be formed on the substrate 500 is therefore sharply reduced.

In particular, in a typical deposition method using a FMM, deposition is performed with the FMM in close physical contact with a substrate in order to prevent formation of a shadow zone on the substrate. However, when the FMM is used in close contact with the substrate, the contact may cause defects, such as scratches on patterns formed on the substrate. In addition, in the contemporary deposition method, the size of the mask has to be the same as the size of the substrate since the mask cannot be moved relative to the substrate. Thus, the size of the mask has to be increased as display devices become larger. It is however not easy to manufacture such a large mask.

In order to overcome this problem, in the thin film deposition apparatus 100″ constructed as the current embodiment, the patterning slit sheet 150 is disposed to be separated and spaced apart from the substrate 500 by a distance (e.g., a predetermined distance D). This may be facilitated by installing the barrier plates 131 to reduce the size of the shadow zone formed on the substrate 500.

As described above, when the patterning slit sheet 150 is manufactured to be smaller than the substrate 500, the patterning slit sheet 150 may be moved relative to the substrate 500 during the process of deposition. Thus, it is no longer necessary to manufacture a large FMM as used in the contemporary deposition method. In addition, since the substrate 500 and the patterning slit sheet 150 are separated from each other, defects caused due to contact therebetween may be prevented. In addition, since it is unnecessary to contact the substrate 500 with the patterning slit sheet 150 during a deposition process, the manufacturing speed may be improved.

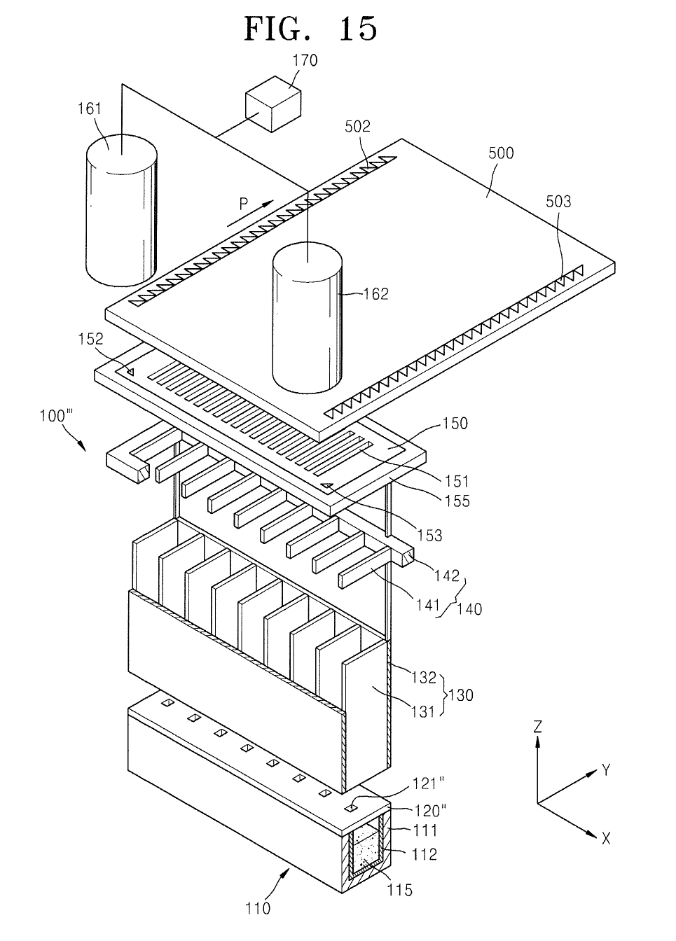

FIG. 15 is a schematic perspective view of a thin film deposition apparatus 100′ constructed as another embodiment of the present invention.

Referring to FIG. 15, the thin film deposition apparatus 100′″ includes a deposition source 110, a deposition source nozzle unit 120, a first barrier plate assembly 130, a second barrier plate assembly 140, and a patterning slit sheet 150.

Although a chamber is not illustrated in FIG. 15 for the convenience of explanation, all the components of the thin film deposition apparatus 100′″ may be disposed within a chamber that is maintained at an appropriate degree of vacuum. The chamber is maintained at an appropriate vacuum in order to allow a deposition material to move in a substantially straight line through the thin film deposition apparatus 100′″.

A substrate 500, which is a deposition target substrate, is disposed in the chamber. The deposition source 110 that contains and heats a deposition material 115 is disposed at an opposite side of the chamber to that in which the substrate 500 is disposed.

Structures of the deposition source 110 and the patterning slit sheet 150 are substantially the same as those in the previous embodiments, and thus a detailed description thereof will not be provided here. The first barrier plate assembly 130 is also the same as the barrier plate assembly 130 of the embodiment described above with reference to FIG. 12, and thus a detailed description thereof will not be provided here.

In the current embodiment, the second barrier plate assembly 140 may be disposed at a side of the first barrier plate assembly 130. In an embodiment, the second barrier plate assembly 140 may be disposed between the first barrier plate assembly 130 and the pattern slit sheet 150. The second barrier wall assembly 140 includes a plurality of second barrier walls 141 and a second barrier wall frame 142 that cover sides of the second barrier walls 141.

The plurality of second barrier plates 141 may be arranged parallel to each other at equal intervals in the X-axis direction. In addition, each of the second barrier plates 141 may be formed to extend parallel to the YZ plane in FIG. 15, i.e., perpendicular to the X-axis direction. The second barrier wall frame 141 may be frame shaped to surround the plurality of second barrier plates 141.

The plurality of first barrier plates 131 and second barrier plates 141 arranged as described above partition a deposition space between the deposition source nozzle unit 120″ and the patterning slit sheet 150. The deposition space is divided by the first barrier plates 131 and the second barrier plates 141 into sub-deposition spaces that respectively correspond to the deposition source nozzles 121″ through which the deposition material 115 is discharged.

The second barrier plates 141 may be disposed to correspond respectively to the first barrier plates 131. In other words, the second barrier plates 141 may be respectively disposed to be parallel to and to be on the same plane as the first barrier plates 131. In one embodiment, each second barrier plate 141 may be respectively aligned with a corresponding first barrier plate 131 in the Z direction. Each pair of the corresponding first and second barrier plates 131 and 141 may be located on the same plane. Although the first barrier walls 131 and the second barrier walls 141 are respectively illustrated as having the same thickness in the Y-axis direction, aspects of the present invention are not limited thereto. In other words, the second barrier plates 141, which need to be accurately aligned with the patterning slit sheet 150, may be formed to be relatively thin, whereas the first barrier plates 131, which do not need to be precisely aligned with the patterning slit sheet 150, may be formed to be relatively thick. This makes it easier to manufacture the thin film deposition apparatus 100′″.

A plurality of the thin film deposition apparatuses 100′″ constructed as the current embodiment may be successively disposed in the first chamber 731 of FIG. 1, as illustrated in FIG. 1. In this case, the plurality of thin film deposition apparatuses 100′″ may be used to deposit different deposition materials, respectively. For example, the plurality of thin film deposition apparatuses 100′ may have different patterning slit patterns, so that pixels of different colors, for example, red, green and blue, may be simultaneously defined through a film deposition process.

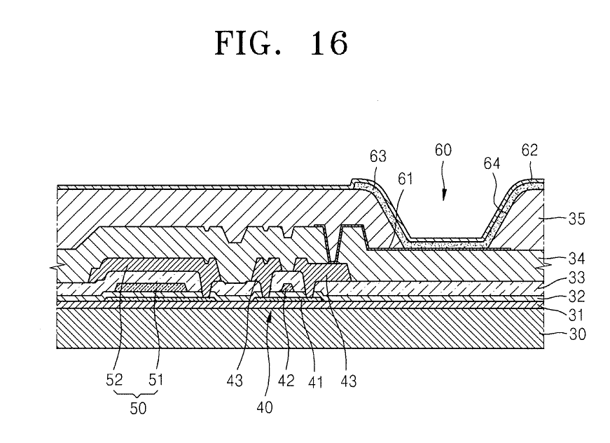

FIG. 16 is a cross-sectional view of an active matrix organic light-emitting display device fabricated by using a thin film deposition apparatus, according to an embodiment of the present invention.

Referring to FIG. 16, the active matrix organic light-emitting display device may be formed on a substrate 30. The substrate 30 may be formed of a transparent material, for example, glass, plastic or metal. An insulating layer 31, such as a buffer layer, is formed on the entire substrate 30.

A thin film transistor (TFT) 40, a capacitor 50, and an organic light-emitting diode (OLED) are disposed on the insulating layer 31, as illustrated in FIG. 16.

A semiconductor active layer 41 is formed on the insulating layer 31 in a pattern (e.g., a predetermined pattern). A gate insulating layer 32 is formed to cover the semiconductor active layer 41. The semiconductor active layer 41 may include a p-type or n-type semiconductor material.

A gate electrode 42 of the TFT 40 is formed in a region of the gate insulating layer 32 corresponding to the semiconductor active layer 41. An interlayer insulating layer 33 is formed to cover the gate electrode 42. Then, the interlayer insulating layer 33 and the gate insulating layer 32 are etched by, for example, dry etching, to form a contact hole for exposing parts of the semiconductor active layer 41.

A source/drain electrode 43 is formed on the interlayer insulating layer 33 to contact the semiconductor active layer 41 exposed through the contact hole. A passivation layer 34 is formed to cover the source/drain electrode 43, and is etched to expose a part of the drain electrode 43. An insulating layer (not shown) may be further formed on the passivation layer 34 so as to planarize the protective layer 34.

In addition, the OLED 60 displays predetermined image information by emitting red, green, or blue light as current flows. The OLED 60 includes a first electrode 61 disposed on the passivation layer 34. The first electrode 61 is electrically connected to the drain electrode 43 of the TFT 40.

A pixel defining layer 35 is formed to cover the first electrode 61. An opening 64 is formed in the pixel defining layer 35, and then an organic emission layer 63 is formed in a region defined by the opening 64. A second electrode 62 is formed on the organic emission layer 63.

The pixel defining layer 35, which defines individual pixels, is formed of an organic material. The pixel defining layer 35 also planarizes the surface of a region of the substrate 30 where the first electrode 61 is formed, and in particular, the surface of the passivation layer 34.

The first electrode 61 and the second electrode 62 are insulated from each other, and respectively apply voltages of opposite polarities to the intermediate layer 63 so as to induce light emission.

The organic emission layer 63 may be formed of a low-molecular weight organic material or a high-molecular weight organic material. When a low-molecular weight organic material is used, the organic emission layer 63 may have a single or multi-layer structure including at least one selected from the group consisting of a hole injection layer (HIL), a hole transport layer (HTL), an emission layer (EML), an electron transport layer (ETL), and an electron injection layer (EIL). Examples of available organic materials may include copper phthalocyanine (CuPc), N,N′-di(naphthalene-1-yl)-N,N-diphenyl-benzidine (NPB), tris-8-hydroxyquinoline aluminum (Alq3), and the like. Such a low-molecular weight organic material may be deposited using vacuum deposition by using one of the thin film deposition apparatuses described above with reference to FIGS. 1 to 16.

After the opening 64 is formed in the pixel defining layer 35, the substrate 30 is transferred to a chamber (not shown).

After the organic emission layer 63 is formed, the second electrode 62 may be formed by the same deposition method as used to form the organic emission layer 63.

The first electrode 61 may function as an anode, and the second electrode 62 may function as a cathode. Alternatively, the first electrode 61 may function as a cathode, and the second electrode 62 may function as an anode. The first electrode 61 may be patterned to correspond to individual pixel regions, and the second electrode 62 may be formed to cover all the pixels.

The first electrode layer 61 may be formed as a transparent electrode or a reflective electrode. Such a transparent electrode may be formed of an indium tin oxide (ITO), an indium zinc oxide (IZO), a zinc oxide (ZnO), or an indium oxide (In₂O₃). Such a reflective electrode may be formed by forming a reflective layer from silver (Ag), magnesium (Mg), aluminum (Al), platinum (Pt), palladium (Pd), gold (Au), nickel (Ni), neodymium (Nd), iridium (Ir), chromium (Cr), or a compound thereof and forming a layer of ITO, IZO, ZnO, or In₂O₃ on the reflective layer. The first electrode 61 may be formed by forming a layer by, for example, sputtering, and then patterning the layer by, for example, photolithography.

The second electrode 62 may also be formed as a transparent electrode or a reflective electrode. When the second electrode 62 is formed as a transparent electrode, the second electrode 62 functions as a cathode. To this end, such a transparent electrode may be formed by depositing a metal having a low work function, such as lithium (Li), calcium (Ca), lithium fluoride/calcium (LiF/Ca), lithium fluoride/aluminum (LiF/Al), aluminum (Al), silver (Ag), magnesium (Mg), or a compound thereof on a surface of the organic emission layer 63 and forming an auxiliary electrode layer or a bus electrode line thereon from ITO, IZO, ZnO, In₂O₃, or the like. When the second electrode layer 62 is formed as a reflective electrode, the reflective layer may be formed by depositing Li, Ca, LiF/Ca, LiF/Al, Al, Ag, Mg, or a compound thereof on the organic emission layer 63. The second electrode 62 may be formed by using the same deposition method as used to form the organic emission layer 63 described above.

The thin film deposition apparatuses constructed as the above embodiments of the present invention may be applied to form an organic layer or an inorganic layer of an organic TFT, and to form layers from various materials. For example, any suitable one of the thin film deposition apparatuses 100 (FIGS. 3-5), 100′ (FIG. 10), 101, 102, 103 (FIG. 11), 100″ (FIGS. 12-14) and 100′″ (FIG. 15) may be used as one or more of the thin film apparatuses 100, 200, 300 or 400 of FIGS. 1 and 2, or as additional thin film apparatuses not specifically shown in FIGS. 1 and 2.

As described above, in a thin film deposition apparatus and a method of manufacturing an organic light-emitting display device according to embodiments of the present invention by using the thin film deposition apparatus, the thin film deposition apparatus may be simply applied to the manufacture of large-sized display devices on a mass scale. In addition, the thin film deposition apparatus and the organic-light-emitting display device may be easily manufactured, may improve manufacturing yield and deposition efficiency, and may allow deposition materials to be reused. Furthermore, the thin film deposition apparatus may be precisely aligned with a substrate during a deposition process.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. A thin film deposition apparatus forming a thin film on a substrate, the apparatus comprising:
a deposition source for discharging a deposition material;
a deposition source nozzle unit disposed at a side of the deposition source, the deposition source nozzle unit including a plurality of deposition source nozzles arranged in a first direction; and
a patterning slit sheet disposed opposite to the deposition source nozzle unit, the patterning slit sheet having a plurality of patterning slits arranged in a second direction perpendicular to the first direction,
wherein deposition is performed while the substrate is moved relative to the thin film deposition apparatus in the first direction,
the patterning slit sheet has a first alignment mark and a second alignment mark that are spaced apart from each other,
the substrate has a first alignment pattern and a second alignment pattern that are spaced apart from each other, and
the thin film deposition apparatus further comprises a first camera assembly for photographing the first alignment mark and the first alignment pattern, and a second camera assembly for photographing the second alignment mark and the second alignment pattern.

2. The thin film deposition apparatus of claim 1, wherein the deposition source, the deposition source nozzle unit, and the patterning slit sheet are integrally formed as a single body.

3. The thin film deposition apparatus of claim 1, wherein the deposition source and the deposition source nozzle unit, and the patterning slit sheet are integrally connected as a single body by connection units for guiding movement of the deposition material.

4. The thin film deposition apparatus of claim 3, wherein the connection units seal a space between the deposition source, the deposition source nozzle unit, and the patterning slit sheet.

5. The thin film deposition apparatus of claim 1, wherein the plurality of deposition source nozzles are tilted at an angle with respect to a vertical line of a surface from which the deposition source nozzles extrude.

6. The thin film deposition apparatus of claim 5, wherein the plurality of deposition source nozzles comprises deposition source nozzles arranged in two rows in the first direction, and
the deposition source nozzles in one of the two rows are tilted to face towards the deposition source nozzles in the other one of the two rows.

7. The thin film deposition apparatus of claim 5, wherein the plurality of deposition source nozzles comprises deposition source nozzles arranged in two rows in the first direction,
the deposition source nozzles of one of the two rows located at a first side of the patterning slit sheet are arranged to face towards a second side of the patterning slit sheet, and
the deposition source nozzles of the other one of the two rows located at the second side of the patterning slit sheet are arranged to face towards the first side of the patterning slit sheet.

8. The thin film deposition apparatus of claim 1, wherein the first alignment pattern comprises a plurality of first marks arranged in the first direction,
the second alignment pattern comprises a plurality of second marks arranged in the first direction, and
the first alignment pattern and the second alignment pattern are spaced apart from each other in the second direction.

9. The thin film deposition apparatus of claim 8, wherein at least one of the first mark or the second mark has a polygonal shape.

10. The thin film deposition apparatus of claim 9, wherein at least one of the first mark or the second mark has a triangular shape.

11. The thin film deposition apparatus of claim 9, wherein the first alignment pattern and the second alignment pattern are formed in the form of a saw tooth.

12. The thin film deposition apparatus of claim 1, wherein a direction in which the first camera assembly and the second camera assembly are arranged is perpendicular to the first direction.

13. The thin film deposition apparatus of claim 1, wherein the first camera assembly and the second camera assembly are disposed over the substrate to correspond to the first alignment mark and the second alignment mark, respectively.

14. The thin film deposition apparatus of claim 1, further comprising a controller for determining a degree to which the substrate and the patterning slit sheet are aligned with each other, based on information captured by the first camera assembly and the second camera assembly.

15. The thin film deposition apparatus of claim 14, wherein the controller is configured to determine the degree to which the substrate and the patterning slit sheet are aligned with each other in the second direction perpendicular to the first direction by comparing a first distance between images of the first alignment pattern and the first alignment mark photographed by the first camera assembly with a second distance between images of the second alignment pattern and the second alignment mark photographed by the second camera assembly.

16. The thin film deposition apparatus of claim 14, wherein the controller is configured to determine whether or not the patterning slit sheet is tilted within a plane formed by the first and second directions and is misaligned to the substrate by comparing an image of the first alignment mark photographed by the first camera assembly with an image of the second alignment mark photographed by the second camera assembly.

17. The thin film deposition apparatus of claim 16, wherein the controller is configured to determine that the patterning slit sheet is tilted within the plane towards the second alignment mark when a width of the image of the first alignment mark is greater than a width of the image of the second alignment mark, and to determine that the patterning slit sheet is tilted within the plane towards the first alignment mark when the width of the image of the first alignment mark is less than the width of the image of the second alignment mark.

18. The thin film deposition apparatus of claim 14, wherein the controller is configured to determine whether or not the substrate is tilted within a plane formed by the first and second directions by comparing an image of the first alignment pattern photographed by the first camera assembly with an image of the second alignment pattern photographed by the second camera assembly.

19. The thin film deposition apparatus of claim 18, wherein the controller is configured to determine that the substrate is tilted within the plane towards the second alignment pattern when a width of the image of the first alignment pattern is greater than a width of the image of the second alignment pattern, and to determine that the substrate is tilted within the plane towards the first alignment pattern when the width of the image of the first alignment pattern is less than the width of the image of the second alignment pattern.

20. The thin film deposition apparatus of claim 14, wherein the substrate and the patterning slit sheet are aligned with each other by moving the substrate or the patterning slit sheet, based on the degree of alignment, determined by the controller.

21. A thin film deposition apparatus for forming a thin film on a substrate, the apparatus comprising:
a deposition source for discharging a deposition material;
a deposition source nozzle unit disposed at a side of the deposition source and including a plurality of deposition source nozzles arranged in a first direction;
a patterning slit sheet disposed opposite to the deposition source nozzle unit and having a plurality of patterning slits arranged in the first direction; and
a barrier plate assembly comprising a plurality of barrier plates that are disposed between the deposition source nozzle unit and the patterning slit sheet in the first direction and that partition a deposition space between the deposition source nozzle unit and the patterning slit sheet into a plurality of sub-deposition spaces,
wherein the thin film deposition apparatus and the substrate are spaced apart from each other,
a process of deposition is performed while the thin film deposition apparatus or the substrate is moved relative to the other.
the patterning slit sheet has a first alignment mark and a second alignment mark that are spaced apart from each other,
the substrate has a first alignment pattern and a second alignment pattern that are spaced apart from each other, and
the thin film deposition apparatus further comprises a first camera assembly for photographing the first alignment mark and the first alignment pattern, and a second camera assembly for photographing the second alignment mark and the second alignment pattern.

22. The thin film deposition apparatus of claim 21, wherein the plurality of barrier plates extend in a second direction substantially perpendicular to the first direction.

23. The thin film deposition apparatus of claim 21, wherein the barrier plate assembly comprises:
a first barrier plate assembly comprising a plurality of first barrier plates, and
a second barrier plate assembly comprising a plurality of second barrier plates.

24. The thin film deposition apparatus of claim 23, wherein the plurality of first barrier plates and the plurality of second barrier plates extend in a second direction substantially perpendicular to the first direction.

25. The thin film deposition apparatus of claim 24, wherein the plurality of first barrier plates are arranged to respectively correspond to the plurality of second barrier plates.

26. The thin film deposition apparatus of claim 21, wherein the deposition source is spaced apart from the barrier plate assembly.

27. The thin film deposition apparatus of claim 21, wherein the barrier plate assembly is spaced apart from the patterning slit sheet.

28. The thin film deposition apparatus of claim 21, wherein the first alignment pattern comprises a plurality of first marks arranged in the first direction,
the second alignment pattern comprises a plurality of second marks arranged in the first direction, and
the first alignment pattern and the second alignment pattern are spaced apart from each other in the second direction.

29. The thin film deposition apparatus of claim 28, wherein at least one of the first mark or the second mark has a polygonal shape.

30. The thin film deposition apparatus of claim 29, wherein at least one of the first mark or the second mark has a triangular shape.

31. The thin film deposition apparatus of claim 29, wherein the first alignment pattern and the second alignment pattern are formed in the form of a saw tooth.

32. The thin film deposition apparatus of claim 21, wherein a direction in which the first camera assembly and the second camera assembly are arranged is perpendicular to the first direction.

33. The thin film deposition apparatus of claim 21, wherein the first camera assembly and the second camera assembly are disposed over the substrate to correspond to the first alignment mark and the second alignment mark, respectively.

34. The thin film deposition apparatus of claim 21, further comprising a controller for determining a degree to which the substrate and the patterning slit sheet are aligned with each other, based on information captured by the first camera assembly and the second camera assembly.

35. The thin film deposition apparatus of claim 34, wherein the controller is configured to determine the degree to which the substrate and the patterning slit sheet are aligned with each other in the first direction by comparing a first distance between images of the first alignment pattern and the first alignment mark photographed by the first camera assembly with a second distance between images of the second alignment pattern and the second alignment mark photographed by the second camera assembly.

36. The thin film deposition apparatus of claim 34, wherein the controller is configured to determine whether or not the patterning slit sheet is tilted within a plane formed by the first and the third directions and is misaligned to the substrate by comparing an image of the first alignment mark photographed by the first camera assembly with an image of the second alignment mark photographed by the second camera assembly.

37. The thin film deposition apparatus of claim 36, wherein the controller is configured to determine that the patterning slit sheet is tilted within the plane towards the second alignment mark in when a width of the image of the first alignment mark is greater than a width of the image of the second alignment mark, and to determine that the patterning slit sheet is tilted within the plane towards the first alignment mark in the first direction when the width of the image of the first alignment mark is less than the width of the image of the second alignment mark.

38. The thin film deposition apparatus of claim 34, wherein the controller is configured to determine whether or not the substrate is tilted within a plane formed by the first and third directions and is misaligned to the patterning slit sheet by comparing an image of the first alignment pattern photographed by the first camera assembly with an image of the second alignment pattern photographed by the second camera assembly.

39. The thin film deposition apparatus of claim 38, wherein the controller is configured to determine that the substrate is tilted within the plane towards the second alignment pattern when a width of the image of the first alignment pattern is greater than a width of the image of the second alignment pattern, and to determine that the substrate is tilted within the plane towards the first alignment pattern when the width of the image of the first alignment pattern is less than the width of the image of the second alignment pattern.

40. The thin film deposition apparatus of claim 34, wherein the substrate and the patterning slit sheet are aligned with each other by moving the substrate or the patterning slit sheet, based on the degree of alignment, determined by the controller.

41. A method of manufacturing an organic light-emitting display device by using a thin film deposition apparatus for forming a thin film on a substrate, the method comprising:
arranging the substrate to be spaced apart from the thin film deposition apparatus by a distance;
depositing a deposition material discharged from the thin film deposition apparatus onto the substrate while the thin film deposition apparatus or the substrate is moved relative to the other; and
aligning the thin film deposition apparatus with the substrate while the thin film deposition apparatus or the substrate is moved relative to the other.

42. The method of claim 41, wherein the depositing of the deposition material on the substrate comprises continuously depositing the deposition material discharged from the thin film deposition apparatus on the substrate while the substrate is moved relative to the thin film deposition apparatus.

43. The method of claim 41, wherein the aligning of the thin film deposition apparatus with the substrate comprises:
photographing an alignment mark on the substrate and an alignment pattern on the thin film deposition apparatus by using a camera assembly;
determining a degree to which the substrate and the thin film deposition apparatus are aligned to each other by comparing images of the alignment mark and alignment pattern photographed by the camera assembly; and
aligning the substrate and the thin film deposition apparatus with each other by moving the substrate or the thin film deposition apparatus, based on the degree of alignment.
